(19) United States
(12) Patent Application Publication
(10) Pub. No.: US 2026/0136990 A1
(43) Pub. Date: May 14, 2026

(54) SEMICONDUCTOR DEVICES HAVING DUMMY DIES AND METHODS OF MAKING THE SAME

(71) Applicant: Taiwan Semiconductor Manufacturing Company Limited, Hsinchu (TW)

(72) Inventors: Meng-Liang LIN, Hsinchu (TW); Chieh-Lung LAI, Taichung City (TW); Hsien-Wei CHEN, Hsinchu City (TW); Kathy Wei YAN, Hsinchu (TW)

(21) Appl. No.: 18/944,313

(22) Filed: Nov. 12, 2024

(51) Int. Cl. H01L 25/18; H01L 21/48; H01L 21/56; H01L 23/00; H01L 23/31; H01L 23/498; H05K 1/18; H10B 80/00

(52) U.S. Cl. CPC H10W 90/00; H10W 42/121; H10W 70/093; H10W 70/65; H10W 74/016; H10W 90/401; H05K 1/181; H10B 80/00; H10W 74/141; H10W 74/15; H10W 90/724; H10W 90/734

(57) ABSTRACT

Semiconductor devices having dummy dies and methods of fabricating semiconductor devices with dummy dies. An embodiment semiconductor device includes an interconnect structure and one or more active devices attached to the interconnect structure, the one or more active devices being electrically connected to the interconnect structure through a plurality of conductive bumps. The semiconductor device includes a dummy die attached to the interconnect structure by an adhesive layer, wherein the adhesive layer comprises one of a die attach film (DAF) layer, a film over wire (FOW) layer, or a non-conductive film (NCF) layer.

### BACKGROUND

Chip-on-wafer (CoW) systems represent an integration paradigm wherein multiple semiconductor dies are interconnected and encapsulated on a common substrate prior to individual packaging. This approach may yield reductions in interconnect parasitics and packaging-related costs. Interconnect structures within CoW systems may use various topologies, including fan-out, stacked die, or 2.5D configurations. Die placement and routing algorithms are to be considered in order to optimize signal integrity and power distribution within the CoW system. Advanced packaging techniques, such as through-silicon vias (TSVs) and hybrid bonding, may be utilized to establish electrical connections between dies and the substrate.

Dummy dies may be incorporated into CoW systems to fulfill specific functionalities. Dummy dies are inert semiconductor dies, which may serve as mechanical or thermal interface components. Such dummy dies may provide structural support or may aide in heat dissipation. Additionally, dummy dies may occupy vacant spaces within the CoW system, facilitating uniform stress distribution and enhancing packaging reliability. Strategic placement of dummy dies may also contribute to optimized electrical performance by reducing parasitic effects and improving signal integrity within the interconnect network.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an example semiconductor device.

FIG. 2A is a vertical cross-sectional view of the semiconductor device having a stress buffer.

FIG. 2B illustrates examples of the dimensions of the stress buffer.

FIG. 2C is a vertical cross-sectional view of an alternative embodiment of the semiconductor device.

FIG. 3 illustrates an example embodiment of the semiconductor device including a silicon interposer with TSVs.

FIG. 4 illustrates an example embodiment of the semiconductor device including an organic interposed with local silicon interconnects (LSIs).

FIGS. 5A-5C illustrate the semiconductor device configured as a chip-on-wafer system.

FIG. 6 illustrates a flow diagram of an example method for fabricating a semiconductor device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Various embodiments of dummy die integration techniques disclosed herein may enable chip-on-wafer (CoW) silicon (Si) stacking, for example, to reduce underfill bleeding width and mitigate package edge and/or corner stress. Bleeding width is the spread of excess adhesive or bonding material beyond a target attachment area in instances in which a die is attached to a substrate. This excess material may lead to defects, such as short circuits or contamination. For example, such defects may be the result of the excess material encroaching on critical areas of the die or substrate. Bleeding width may be measured, for example, by a total width of the spread of the excess material or by the width of the spread beyond the target attachment area.

CoW Si die stacking refers to the process of stacking silicon dies (for example, thin slices of semiconductor material) onto a wafer to create a multi-die package. This CoW Si die stacking technique may be used in semiconductor packaging to increase the density and performance of integrated circuits.

Dummy filler dies (or more simply dummy dies) are non-functional silicon dies that may be used to fill gaps in the wafer. For example, the use of dummy dies may ensure a uniform thickness in a die stack. The use of dummy dies may also provide support during the stacking process. These dummy dies may be positioned in various configurations to meet design goals and targets.

Underfill is a material used to fill the space between stacked dies (including dummy filler dies), for example, to provide mechanical support and protect against thermal and mechanical stress. Reducing the bleeding width of underfill material may include minimizing the spread of the underfill material beyond a target area. The minimization of the spread of underfill material may be useful for maintaining the integrity and reliability of the package.

Edge and corner stress mitigation may involve techniques to reduce mechanical stress at the edges and corners of the package. This may be useful, for example, to prevent cracking or damage to the silicon dies and the overall package, which may occur due to thermal expansion, mechanical handling, or other stresses.

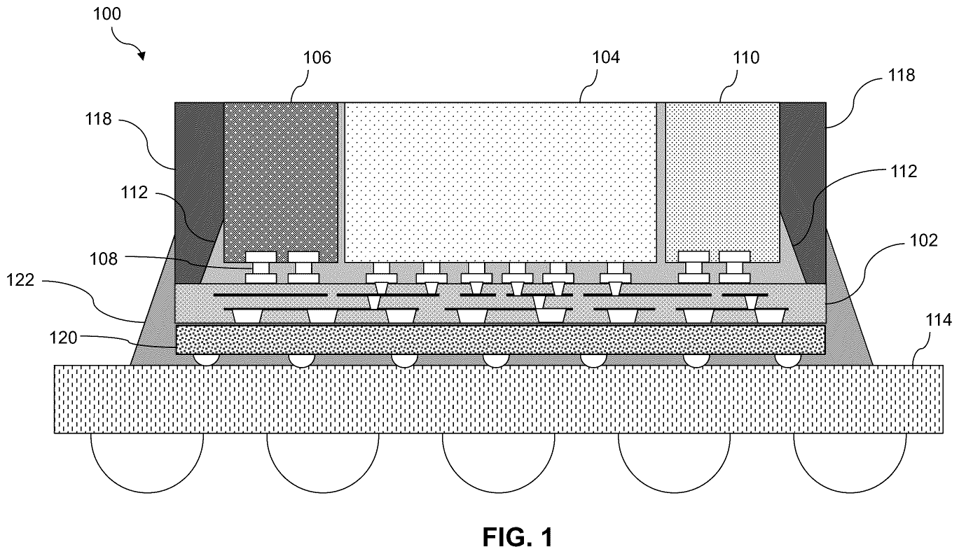

FIG. 1 is a vertical cross-sectional view of an example semiconductor device 100. The semiconductor device 100 may be used, for example, in a CoW system. The semiconductor device 100 includes an interconnect structure 102 and one or more active devices 104, 106 attached to the interconnect structure 102. The active devices 104, 106 are electrically connected to the interconnect structure 102 through conductive bumps 108. In some embodiments, the interconnect structure 102 may be positioned above an interposer 120. The semiconductor device 100 includes a substrate 114, for example, a silicon substrate. In some embodiments, the interposer 120 may be positioned vertically between the interconnect structure 102 and the substrate 114. In other embodiments the interconnect structure 102 may be electrically connected directly to the substrate 114.

The interconnect structure 102 (sometimes referred to as a redistribution layer, RDL) in the semiconductor device 100 may be configured for establishing electrical connections between the active devices 104 and 106 and potentially other circuits. In some embodiments, the interconnect structure 102 comprises multiple layers of conductive and insulating materials, forming a network that facilitates signal transmission and power distribution across the semiconductor device 100. The conductive layers may be made of metals like copper or aluminum, which provide low-resistance pathways for electrical currents. These layers may be interspersed with dielectric materials, such as silicon dioxide or low-k dielectrics, which serve to insulate the conductive paths and prevent electrical connections (i.e., shorting) between adjacent layers.

The conductive bumps 108 are configured for electrically connecting the active devices 104 and 106 to the interconnect structure 102. The use of conductive bumps 108 may be useful for providing efficient signal transfer and power delivery. These conductive bumps 108, which may be formed from solder or other conductive materials, provide the necessary mechanical and electrical interface between the active devices 104, 106 and the interconnect structure 102.

In some embodiments, the conductive bumps 108 are microbumps. The conductive bumps 108 may electrically connect conductive bonding pads on the bottom surfaces of the active devices 104, 106 to conductive bonding pads on the upper surface of the interconnect structure 102.

In some embodiments, the conductive bumps 108 in the form of microbumps may include a plurality of first metal stacks, such as a plurality of Cu-Ni-Cu stacks, located on the bottom surfaces of the active devices 104, 106, and a plurality of second metal stacks (e.g., Cu—Ni—Cu stacks) located on the upper surface of the interconnect structure 102. A solder material, such as tin (Sn), may be located between respective first and second metal stacks to electrically connect the active devices 104, 106 to the interconnect structure 102. Other suitable materials for the conductive bumps 108 are within the contemplated scope of disclosure.

The conductive bumps 108 are typically formed through a multi-step process. First, metallization layers, such as copper-nickel-copper stacks, are deposited onto the surfaces of the active devices 104, 106 and the interconnect structure 102. These metal stacks serve as a foundation for the conductive bumps 108. Subsequently, a solder material, commonly tin, is applied to the metal stacks using techniques like electroplating or sputtering. The solder forms the core of the conductive bumps 108. To enhance reliability and mechanical stability, additional layers, such as capping layers or barrier layers, may be deposited on top of the solder. Precise control of deposition parameters, including thickness, uniformity, and adhesion, may be configured to achieve optimal bump performance.

In some embodiments, manufacturing techniques, such as photolithography and chemical vapor deposition, are used to precisely pattern and build the interconnect structure 102, potentially enabling high density and fine pitch interconnections that support the increasing complexity and miniaturization of semiconductor devices. The interconnect structure 102 may be configured to manage thermal dissipation effectively, as the concentrated heat generated by the active devices 104, 106 may impact the performance and longevity of the device 100.

The active devices 104, 106 may include, for example, a system-on-chip (SoC) device 104 and a high bandwidth memory (HBM) device 106. The SoC device 104 may integrate multiple functional components, such as processors, memory controllers, and input/output interfaces, onto a single chip, enabling compact and efficient processing capabilities. The HBM device 106, in some embodiments, provides a high-speed memory solution that supports rapid data transfer rates and large bandwidth, which may be useful for demanding applications such as graphics processing, artificial intelligence, and data-intensive computing. Together, the active devices 104, 106 enhance the overall functionality and performance of the semiconductor device 100, potentially making it suitable for a wide range of applications, including advanced computing systems, gaming consoles, and data centers.

The semiconductor device 100 includes a dummy die 110 attached to the interconnect structure 102. In the example shown in FIG. 1, the dummy die 110 is attached to the interconnect structure 102 through the conductive bumps 108. In general, the dummy die 110 is a structure that lacks active circuitry.

The dummy die 110 may be configured in a variety of geometric shapes, such as rectangular or other suitable forms, and may be composed entirely or predominantly of the same material. In some embodiments, the dummy die 110 may be formed of the same material as the active devices 104, 106 or other surrounding components. The primary functions of the dummy die 110 may be to occupy space and provide mechanical support or thermal management within the interconnect structure 102, without contributing to the electrical functionality of the semiconductor device 100.

In some embodiments, the dummy die 110 may be further configured to balance the mechanical stresses within the semiconductor device 100. By providing a physical counterpart to the active devices 104, 106, the dummy die 110 may be configured such that the package experiences uniform stress distribution during thermal cycling and mechanical handling. In some embodiments, this balance may mitigate against the risk of warping or deformation of the semiconductor device 100. Such warping or deformation may lead to failures or reduced performance of the active components. Since the dummy die 110 is attached to the interconnect structure 102 through conductive bumps 108, the dummy die 110 may further contribute to the overall mechanical integrity of the device.

In some embodiments, the inclusion of the dummy die 110 may simplify the assembly process. By maintaining a consistent die layout and footprint, the dummy die 110 allows for standardized processes and equipment to be used in the packaging and testing stages, improving yield and reducing costs.

In some embodiments, the dummy die 110 may be strategically placed to optimize the thermal profile of the semiconductor device 100. Acting as a heat spreader, the dummy die 110 may help dissipate heat away from critical active components (e.g., active dies 104, 106), which may be useful for enhancing thermal management and ensuring stable operation under high-performance conditions. The material composition and thickness of the dummy die 110 may be selected to match the thermal and mechanical properties of the active dies 104, 106, which may be useful in promoting uniform behavior under thermal stress.

The semiconductor device 100 includes an underfill layer 112 disposed between the active devices 104, 106 and the interconnect structure 102. The underfill layer 112 in the semiconductor device 100 may be useful in enhancing the mechanical stability and reliability of the device. The underfill layer 112 may be bounded on one side by the dummy die 110 and the adhesive layer 116.

Positioned between the active devices 104, 106 and the interconnect structure 102, the underfill layer 112 may be composed from any suitable material. For example, in some embodiments, the underfill layer 112 comprises a thermosetting polymer material. This polymer, which may be epoxy-based, is selected for its ability to provide mechanical support and distribute thermal and mechanical stresses that arise during the operation of the semiconductor device 100.

In some embodiments, the underfill material is dispensed in a liquid form and subsequently cured to solidify, encapsulating the conductive bumps 108 and filling any gaps between the die 104, 106 and the interconnect structure 102. This process may be useful, for example, to mitigate the risk of solder joint failure, which can occur due to the coefficient of thermal expansion (CTE) mismatch between the silicon die and the substrate 114.

The underfill layer 112 may also be useful in protecting the active devices 104, 106 and interconnect structure 102 from environmental contaminants and moisture ingress, which may degrade the performance and longevity of the semiconductor device 100. The adhesive properties of the underfill material may be useful for further securing the attachment of the dummy die 110 to the interconnect structure 102, enhancing the overall structural integrity of the semiconductor device 100.

Furthermore, the choice of underfill material and its application process can be selected to achieve specific thermal and mechanical properties, tailored to the requirements of the application for the semiconductor device 100. This customization may include, for example, adjusting the filler content in the epoxy resin or modifying the curing process to improve thermal conductivity or reduce residual stress.

Potential issues such as underfill bleeding, delamination, and cracking at the active devices 104, 106 or edge of the dummy die 110 and underfill layer 112 may arise due to concentrated stress. These problems may occur, for example, because of the mismatched coefficients of thermal expansion (CTE) between the materials used in the semiconductor device 100.

In instances in which the semiconductor device 100 undergoes thermal cycling during operation, the different rates of expansion and contraction may lead to mechanical stress at the interfaces. This mechanical stress may cause the underfill material to bleed, which refers to the migration of the low-viscosity components of the underfill out of the intended encapsulation area, potentially compromising the integrity of the solder joints and weakening the mechanical bond.

Delamination and cracking are further consequences of this concentrated mechanical stress. The mechanical stress may be concentrated at corners and at interfaces between the active devices 104, 106 and the dummy die 110 and the interconnect structure 102. Stress concentration at corners and interfaces in semiconductor devices may be due to geometric discontinuities. Potentially abrupt changes in material properties or shape disrupt the uniform distribution of stress, causing it to concentrate at these points. Additionally, different materials have varying coefficients of thermal expansion, leading to differential expansion and contraction during temperature fluctuations. Differential expansion and contraction may exacerbate stress concentration at interfaces.

Delamination refers to the separation of the underfill material from the active devices 104, 106, creating voids that may exacerbate the mechanical stress and lead to further propagation of cracks. These cracks may extend through the underfill layer 112 and into solder joints or active device 104, 106, potentially affecting the electrical performance and reliability of the semiconductor device 100.

The edge of the dummy die 110 may be particularly susceptible to these failures due to the abrupt change in mechanical properties and the concentration of stress in these regions. Effective mitigation strategies may include optimizing the underfill material properties, such as improving its adhesion strength and flexibility, and refining thermal management techniques to minimize the CTE mismatch effects. Additionally, careful control of the underfill dispensing and curing processes may help reduce the incidence of bleeding and ensure a more uniform and robust encapsulation.

FIG. 1 shows an example mold 118 that horizontally surrounds the active devices 104, 106 and the dummy die 110. The example mold 118 may provide structural support and environmental protection for the active devices 104, 106 and the dummy die 110. The mold 118 may horizontally surround the active devices 104, 106 and the dummy die 110, encapsulating them to shield against physical damage, contamination, and moisture. The material of the mold 118 may be a thermosetting polymer, chosen for its mechanical properties and thermal stability. The encapsulation process may include placing the semiconductor device 100 in a mold cavity and injecting the mold compound, which then cures to form a solid protective layer. The mold 118 may also play a role in thermal management by dissipating heat generated by the active devices 104, 106 during operation.

In some embodiments, the semiconductor device 100 may include an additional underfill layer 122 that may be formed after the mold 118 and may serve, for example, to protect the interposer 120. The additional underfill layer 122 may extend from the mold 118 to surround the interconnect structure 102 and the interposer 120 and to contact the substrate 114. The additional underfill layer 122 may include the same material used for the underfill layer 112 or may include a different underfill material.

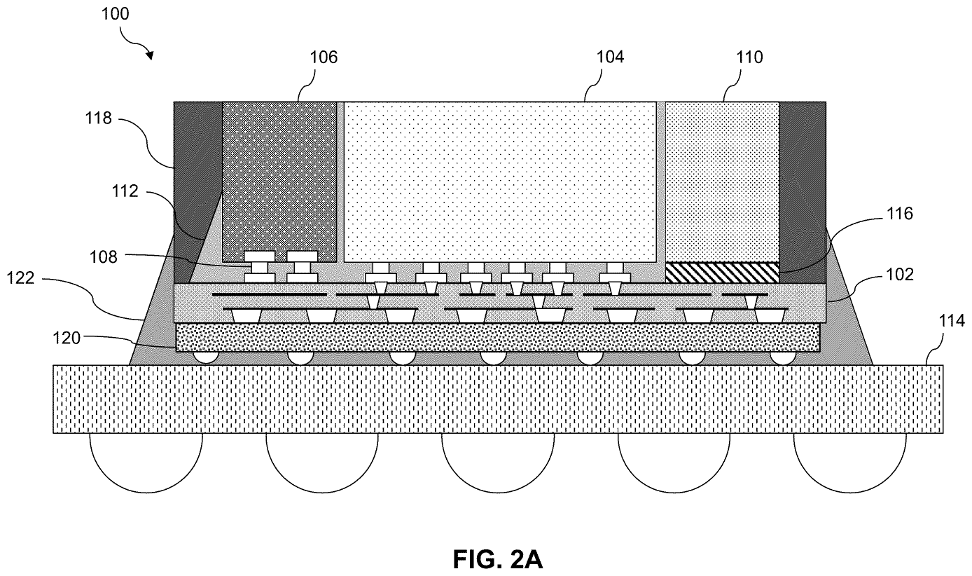

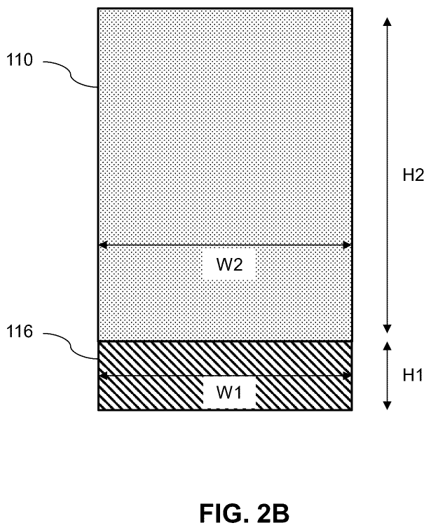

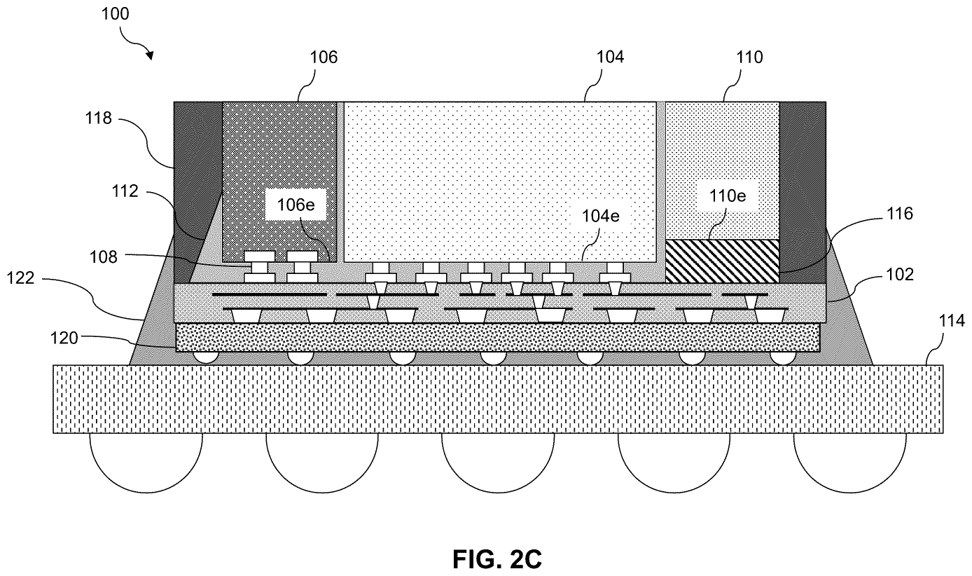

FIG. 2A is a vertical cross-sectional view of the semiconductor device 100 consistent with an embodiment disclosed herein. In an embodiment, the dummy die may be adhered to the interconnect structure 102 with an adhesive layer 116 in lieu of the conductive bumps 108. The adhesive layer 116 may provide a stress buffer that attaches the dummy die 110 to the interconnect structure 102. The adhesive layer 116 may mitigate mechanical stress and enhance structural integrity. Specific examples of the adhesive layer 116 include, but are not limited to, a die attach film (DAF) layer, a film over wire (FOW) layer, or a non-conductive film (NCF) layer. These types of adhesive layers provide reliable attachment and stress buffering, contributing to the overall durability and performance of the semiconductor device 100. In particular, the adhesive layer 116 may be useful, for example, to enlarge the underfill crack-free window. Further the adhesive layer 116 may prevent excess underfill material from reaching the corner regions under the dummy die 110.

FIG. 2B illustrates examples of the dimensions of the adhesive layer 116. FIG. 2B shows the vertical height H1 of the adhesive layer 116, the horizontal width W1 of the adhesive layer 116, the horizontal width W2 of the dummy die 110, and the vertical height H2 of the dummy die 110.

The height H1 of the adhesive layer 116 may be selected, for example, for corner edge stress mitigation and package warpage management. In some embodiments, the height H1 of the adhesive layer 116 is based on the size of the dummy die 110. For example, in instances in which the dummy die 110 has dimensions smaller than 2×2 mm, the height H1 of the adhesive layer 116 may be less than 50 μm. In another example, in instances in which the dummy die 110 has dimensions larger than 10×10 up to 30×30 mm, the height H1 of the adhesive layer 116 may be between 100 μm and 200 μm to cover potential die warpage for better dummy die 110 flatness. In some embodiments, the adhesive layer 116 has a height H1 greater than or equal to 1 μm and less than or equal to 200 μm. For example, the adhesive layer 116 may have a height H1 of 20 μm, although greater or smaller heights of the adhesive layer 116 may be used For example, the height H1 may range from 1 μm to 200 μm. The height H1 of the adhesive layer 116 may be selected to ensure robust mechanical bonding between the dummy die 110 and the interconnect structure 102, while also mitigating thermal and mechanical stresses during operation.

In some embodiments, the dummy die 110 has a width W2, 0.5≤W1/W2≤1, and W1>10 μm. As such, the width W1 of the adhesive layer 116 may be less than or equal to the width W2 of the dummy die 110, without being less than half the width W2 of the dummy die 110.

In some embodiments, the ratio of the height H2 of the dummy die 110 to the height H1 of the adhesive layer 116 is between 100:1 and 500:1. The optimal ratio of dummy die height H2 to adhesive layer height H1 may vary significantly based on specific process parameters, materials, and desired outcomes. Lower ratios (closer to 100:1) may be suitable for heavier dummy dies or when high adhesive strength is desired. Higher ratios (closer to 500:1) may be suitable for lighter dummy dies or when maximizing bond area is a priority. In general, the adhesive layer 116 height H1 is selected to be thick enough to distribute stress evenly and thin enough to prevent excessive strain.

In embodiments in which the adhesive layer 116 is a die attach film (DAF), the DAF may be composed of a thermally and chemically stable polymer material that exhibits strong adhesion properties. Upon application, the DAF undergoes a curing process that results in a bond between the dummy die 110 and the interconnect structure 102. The bond ensures that the components remain securely attached under various thermal and mechanical stresses.

The polymer used in the DAF may be a high-performance material such as epoxy, polyimide, or an acrylic-based compound. These polymers may be selected for their excellent thermal stability, mechanical strength, and chemical resistance, ensuring that the adhesive layer 116 may withstand the rigorous conditions of semiconductor device operation.

The process to apply the DAF may involve several steps. Initially, the adhesive may be supplied in the form of a thin film or tape that is pre-cut to the specified dimensions. This thin film or tape may be aligned and placed onto the surface of the interconnect structure 102. Following placement, the dummy die 110 may be positioned on top of the adhesive layer 116. For example, a pick and place (PnP) may locate the dummy die 110 into position on the adhesive layer 116.

The adhesive layer 116 is then subjected to a curing process. The curing process may include the application of heat, pressure, or a combination of both. The curing process may activate the polymer that forms the adhesive layer 116, causing the polymer to flow and conform to the surfaces of the dummy die 110 and interconnect structure 102. The flowable polymer may fill in any micro-gaps and establish a strong, uniform bond between the adhesive layer 116 and the dummy die 110. The curing process cycle may be controlled to achieve target adhesion properties, ensuring the adhesive layer performs effectively as a stress buffer and mechanical attachment medium within the semiconductor device 100. In some embodiments, a curing temperature less than or equal to 250° C. is used and a pressure less than or equal to 50 N is used for the die attach process.

In embodiments in which the adhesive layer 116 is configured as a film over wire (FOW) layer or a non-conductive film (NCF) layer, the adhesive layer 116 provides specific functional benefits tailored to the requirements of semiconductor device 100. The FOW layer may be used in wire bonding applications in which the FOW layer encapsulates and protects the fine wire connections between the dummy die 110 and the interconnect structure 102. In embodiments in which adhesive layer 116 includes FOW, the adhesive layer 116 may be composed of a polymer matrix that provides sufficient adhesion and mechanical protection for the delicate wire bonds. The polymer matrix prevents wire sweep and ensures electrical integrity during thermal cycling and mechanical stress.

In embodiments in which the adhesive layer 116 includes a NCF layer, the adhesive layer 116 may be configured to provide a non-conductive adhesive solution for attaching the dummy die 110 to the interconnect structure 102 without interfering with the electrical performance of nearby conductive elements. The NCF layer is typically made from epoxy or acrylic polymers that cure to form a rigid, insulating barrier. By using such a NCF layer made from epoxy or acrylic polymers ensures that no electrical pathways are created between the dummy die 110 and the interconnect structure 102, maintaining the desired electrical isolation.

The process to apply both FOW and NCF layers involves precise placement of the film, followed by a controlled curing process that may include heat, pressure, or UV light exposure. The process may be useful for ensuring a reliable and durable bond that enhances the structural integrity and performance of the semiconductor device 100.

FIG. 2C is a vertical cross-sectional view of an alternative embodiment of the semiconductor device 100. In the illustrated embodiment, a bottom surface 110e of the dummy die 110 may distally spaced further from the substrate 114 than bottom surface 104e of active device 104 and/or bottom surface 106e of the active device 106. The bottom surface 110e of the dummy die 110 may be raised vertically from the substrate 114 by virtue of selecting a height H1 of the adhesive layer 116 that raises the bottom surface 110e of the dummy die 110 over the bottom surface 104e of active device 104 and/or bottom surface 106e of the active device 106.

The height difference between the bottom surface 110e of the dummy die 110 and the bottom surface 104e of active device 104 and/or bottom surface 106e of the active device 106 may be useful, for example, to provide better control of the underfill material 112. By keeping the bottom surface 110e of the dummy die 110 distally spaced further from the substrate 114 than the bottom surface 104e of active device 104 and/or bottom surface 106e of the active device 106, the adhesive layer 116 may reduce the risk of the underfill material 112 seeping into unwanted regions. The seepage of the underfill material 112 into unwanted regions may cause issues like cracking or delamination at the interface between the active devices 104, 106 and the interconnect structure 102. The raised dummy die 110 and thicker adhesive layer 116 may act as a barrier, helping to block the flow of underfill material 112.

The height difference may also be useful, for example, to accommodate different thermal expansion rates between the dummy die 110 and the active devices 104, 106. Since the active devices 104, 106 may generate more heat than the dummy die 110, the illustrated embodiment may allow more flexibility for the active devices 104, 106 to expand without directly interacting with the dummy die 110 to reduce the risk of mechanical stress or deformation affecting the performance of the active devices 104, 106.

The height difference may also be useful, for example, to help balance mechanical forces within the semiconductor device 100 for warpage control. The thickness of the adhesive layer 116 may act as a buffer to absorb stress and maintain structural integrity. Moreover, the height difference may be useful, for example, to provide additional electrical isolation, particularly if the adhesive layer 116 is made from a non-conductive material like a DAF. This may reduce the risk of electrical interference between the dummy die 110 and the active devices 104, 106.

The semiconductor device 100 of FIGS. 2A-2C may be configured as including an interposer 120. In some embodiments, the semiconductor device 100 is configured as including a silicon interposer 120a with through-silicon vias (TSVs) 300. In some embodiments, the semiconductor device 100 is configured as including an organic interposer 120b with molding and local silicon interconnects (LSIs) 400.

An interposer 120 (120a, 120b) in semiconductor device 100, as depicted in FIGS. 2A-2C , may be constructed using organic materials such as epoxy resins or bismaleimide triazine (BT) substrates. These materials offer flexibility, lower cost, and compatibility with standard printed circuit board (PCB) manufacturing processes. The interposer 120 may include multiple layers of metal traces and vias embedded within the organic substrate to facilitate electrical connections between the semiconductor die and the package substrate. The interposer 120, in some embodiments, provides routing for signal lines, power distribution, and ground planes, optimizing the electrical performance and reducing signal interference.

Additionally, the inclusion of molding compounds and local silicon (local Si) regions may enhance the mechanical stability and thermal management of the package. The incorporation of advanced interconnect technologies allows for the accommodation of complex circuit designs within a compact footprint, contributing to the overall efficiency and performance of the semiconductor device 100.

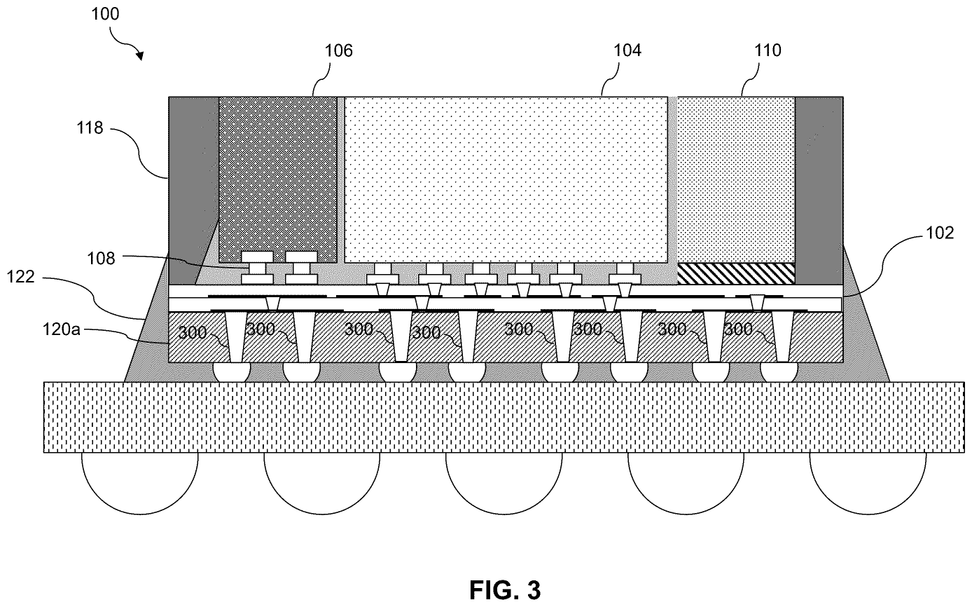

FIG. 3 illustrates an example embodiment of the semiconductor device 100 wherein the interconnect structure 102 is positioned above the silicon interposer 120a with TSVs 300. The silicon interposer 120a may be fabricated from a silicon wafer, which may provide a rigid and thermally conductive platform for high-density interconnections.

The TSVs 300 are vertical electrical connections that pass through the silicon substrate, providing direct electrical paths between the top and bottom surfaces of the silicon interposer 120a. This configuration may reduce the signal path length, which may be useful for minimizing signal delay and power consumption. The high precision of silicon processing may allow for the creation of fine-pitch interconnects and high aspect ratio TSVs, supporting the integration of multiple semiconductor dies in a stacked configuration.

The compatibility of the silicon interposer 120a with lithography techniques may be useful for the precise alignment and formation of micro-bumps and redistribution layers (RDL), enhancing the overall electrical performance and reliability of the semiconductor device 100. The silicon interposer 120a with TSVs 300 may therefore be suitable for high-performance computing applications and other areas requiring exceptional electrical and thermal performance.

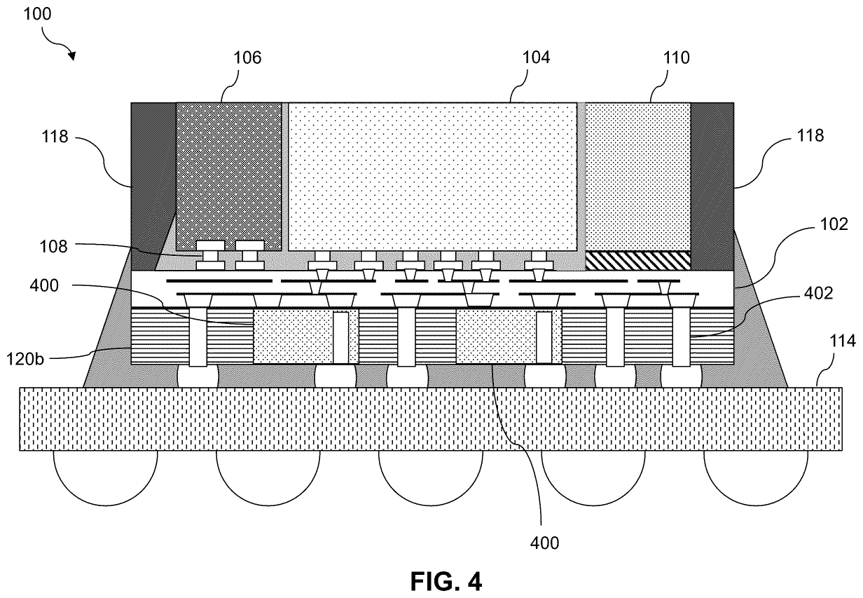

FIG. 4 illustrates an example embodiment of the semiconductor device 100 as including an organic interposer 120b with local silicon interconnects (LSIs) 400. In this configuration, the inclusion of LSIs 400 introduces localized regions of silicon to enhance the interconnect performance. The LSIs 400 may serve as high-density interconnects within the organic substrate, enabling precise and efficient electrical connections between the semiconductor dies and other components. These silicon interconnects may be fabricated using lithography and etching techniques, allowing for the creation of fine-pitch interconnects that are capable of handling high-speed signal transmission and power distribution.

By integrating the LSIs 400 within the organic interposer 120b, the semiconductor device 100 may benefit from the mechanical robustness and thermal conductivity of silicon, while maintaining the advantageous properties of the organic material, such as flexibility and lower manufacturing costs. This hybrid approach may be useful to configure the overall performance and reliability of the semiconductor device 100, making it suitable for applications requiring high interconnect density and superior electrical characteristics.

As shown in FIG. 4, the semiconductor devices also may include at least one through mold via (TMV) 402. TMV technology involves creating vias that pass through a molding compound used in semiconductor packages, allowing for electrical connections between different layers or components.

After the active devices 104, 106 and dummy die 110 are attached and encapsulated with the mold 118, the at least one via 402 is formed through this mold material. The via 402 may provide a pathway for electrical connections from the surface of the molding compound down to the underlying interconnect structure 102 or substrate 114.

TMVs enable the routing of signals, power, and ground connections through the mold compound, allowing for a more compact and integrated package design. This may be useful in advanced packaging technologies where space and interconnect density are critical.

In some embodiments of the semiconductor device 100, TMVs may facilitate connections between the active devices 104, 106 mounted above the interposer 120b and the underlying PCB or package substrate 114. This may allow for a high degree of integration and efficient use of space. The use of TMVs may also enhance the mechanical stability and thermal performance of the package by providing robust vertical interconnects through the molding compound.

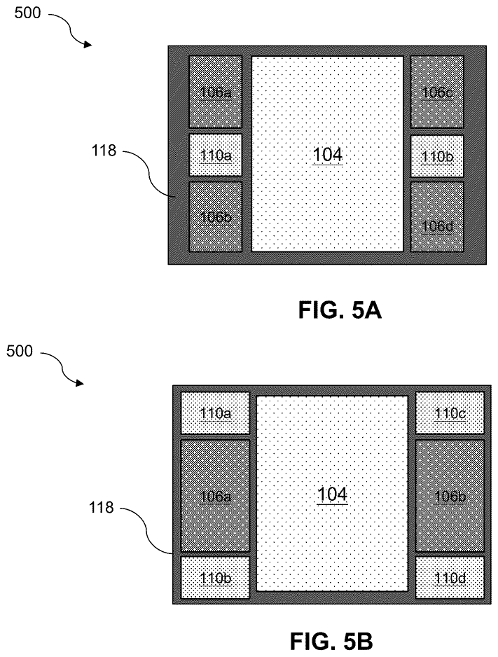

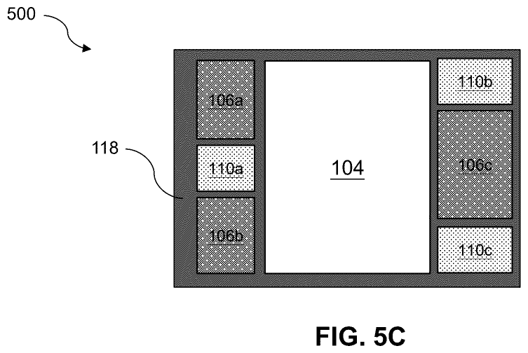

FIGS. 5A-5C illustrate plan views of the semiconductor device 100 configured as a chip-on-wafer system 500. The chip-on-wafer system 500 includes at least one SoC device 104, a number of HBMs 106a-d adjacent to the SoC device 104, and a number of dummy dies 110a-d adjacent to the SoC device 104. Each dummy die of the dummy dies 110a-d is attached to an interconnect structure 102 by an adhesive layer 116 comprising one of a DAF layer, a FOW layer, or a NCF layer.

FIGS. 5A-5C illustrate HBMs 106a-d as an example of active devices; however, in general, the chip-on-wafer system 500 may include any appropriate type of active devices adjacent to the SoC device 104. For example, the chip-on-wafer system 500 can include one or more application-specific integrated circuits (ASICs), field-programmable gate arrays (FPGAs), graphics processing units (GPUs), digital signal processors (DSPs), memory devices such as dynamic random access memory (DRAM), analog integrated circuits, or sensors.

FIG. 5A is a top view of the chip-on-wafer system 500 having a first example layout. A first dummy die 110a is positioned between a first HBM 106a at a first corner of the chip-on-wafer system 500 and a second HBM 106b at a second corner of the chip-on-wafer system 500. A second dummy die 110b is positioned between a third HBM 106c at a third corner of the chip-on-wafer system 500 and a fourth HBM 106d at a fourth corner of the chip-on-wafer system 500.

In the layout shown in FIG. 5A, the strategic placement of dummy dies 110a-b between the HBMs 106a-d at the corners of the chip-on-wafer system 500 serves multiple technical purposes. The dummy dies 110a-b may help to balance the mechanical stresses that arise during the thermal cycles of manufacturing and operation.

By positioning these dummy dies 110a-b between the HBMs 106a-d, which are located at the corners where stress concentration may be higher, the system 500 mitigates potential warping or damage to the delicate structures of the active devices. Moreover, these dummy dies 110a-b may act as placeholders to maintain the alignment and spacing of the active dies during the assembly process, ensuring precise placement of the active dies 104, 106 and interconnect formation. The arrangement may also aid in forming the signal routing paths by providing clear delineation between the HBMs 106a-d, reducing the potential for signal interference and enhancing the overall performance of the chip-on-wafer system 500.

FIG. 5B is a top view of the chip-on-wafer system 500 having a second example layout. A first HBM 106a is positioned between a first dummy die 110a at a first corner of the chip-on-wafer system 500 and a second dummy die 110b at a second corner of the chip-on-wafer system 500. A second HBM 106b is positioned between a third dummy die 110c at a third corner of the chip-on-wafer system 500 and a fourth dummy die 110d at a fourth corner of the chip-on-wafer system 500.

In the alternative layout illustrated in FIG. 5B, the placement of the HBMs 106a-b between the dummy dies 110a-d at the corners reflects a different approach to configuring the system's mechanical and thermal stability. This configuration allows for a more distributed thermal profile across the chip-on-wafer system 500, as the dummy dies 110a-d, which do not generate significant heat, may act as thermal buffers around the heat-generating HBMs 106a-d. This may lead to more uniform temperature distribution and reduced thermal gradients, which may be beneficial for the reliability and longevity of the semiconductor device.

Additionally, this layout may facilitate efficient power distribution and signal integrity by reducing the congestion of interconnects around the central active regions. The separation of the HBMs 106a-b by the dummy dies 110a-d also allows for the inclusion of additional passive components or circuitry within the system 500, further enhancing the functionality and performance of the chip-on-wafer system 500.

FIG. 5C is a top view of the chip-on-wafer system 500 having a third example layout. A first dummy die 110a is positioned between a first HBM 106a at a first corner of the chip-on-wafer system 500 and a second HBM 106b at a second corner of the chip-on-wafer system 500. A third HBM 106c is positioned between a second dummy die 110b at a third corner of the chip-on-wafer system 500 and a third dummy die 110c at a fourth corner of the chip-on-wafer system 500.

The following discussion now refers to a number of methods and method steps. Although the method steps are discussed in specific orders or are illustrated in a flow chart as being performed in a particular order, no order is required unless expressly stated or required because a step is dependent on another step being completed prior to the step being performed.

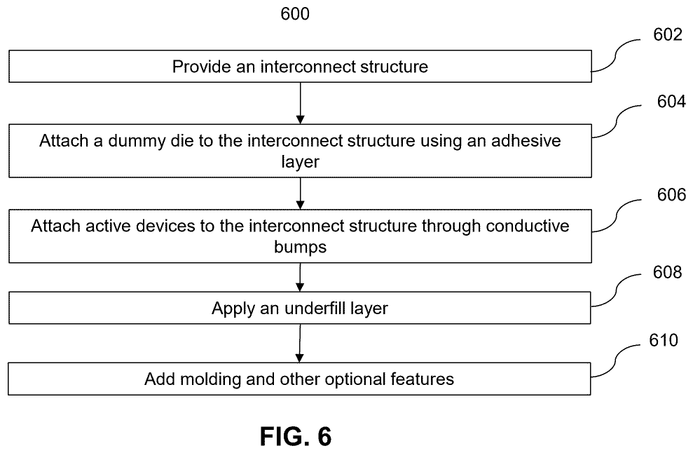

Embodiments are now described in connection with FIG. 6, which illustrates a flow diagram of an example method 600 for fabricating a semiconductor device 100 according to some embodiments of the present disclosure.

In an embodiment method 600, step 602 comprises providing an interconnect structure 102 of the semiconductor device 100. Providing the interconnect structure 102 may include, for example, forming a redistribution layer by sequentially forming metallization layers separated by dielectric layers.

In an embodiment method 600, step 604 comprises attaching a dummy die 110 to the interconnect structure 102 using an adhesive layer 116. The adhesive layer 116 comprises one of a die attach film (DAF) layer, a film over wire (FOW) layer, or a non-conductive film (NCF) layer. Attaching the dummy die 110 may include performing a curing process that results in a bond between the dummy die 110 and the interconnect structure 102.

In an embodiment method 600, step 606 comprises attaching one or more active devices 104, 106 to the interconnect structure 102. Attaching the active devices 104, 106 includes electrically connecting the active devices 104, 106 to the interconnect structure 102 through conductive bumps 108.

In some embodiments, a metal layer, typically composed of solder or a combination of metals such as copper, tin, and silver, is deposited onto the contact pads of the active devices 104, 106. This deposition may be achieved through techniques such as electroplating or sputtering, which allow for the accurate control of the bump material's thickness and composition. Following deposition, a photolithographic process may be employed to define the bump pattern, where a photoresist layer is applied, exposed to a pattern, and developed to create openings that correspond to the desired bump locations.

Next, the metal layer may be selectively etched, leaving behind the defined bumps. These bumps are then reflowed by heating them to a temperature above their melting point, causing them to form uniform, hemispherical shapes that ensure optimal contact and alignment with the corresponding pads on the interconnect structure 102. The reflow process may be carried out in a controlled atmosphere, such as nitrogen, to prevent oxidation and ensure the integrity of the bumps. Finally, any residual photoresist and unwanted metal may be removed through cleaning processes, resulting in clean, conductive bumps ready for the attachment of the active devices 104, 106.

In an embodiment method 600, step 608 comprises applying an underfill layer 112 between the one or more active devices 104, 106 and the interconnect structure 102 to provide mechanical support and enhance the reliability of the conductive bumps 108. The underfill material, which may be an epoxy-based resin, is dispensed in a controlled manner around the perimeter of the attached active devices 104, 106. Capillary action may draw the underfill material under the devices, filling the gaps between the active devices 104, 106 and the interconnect structure 102, and completely encapsulating the conductive bumps 108. The underfill layer 112 may be applied such that the dummy die 110 and the adhesive layer 116 spatially blocks a flow of the underfill layer 112, for example, preventing the underfill layer 112 from flowing beyond the adhesive layer 116.

Once the underfill is dispensed and uniformly distributed, it may undergo a curing process. This is usually performed in an oven or using UV light, depending on the specific properties of the underfill resin. The curing process solidifies the underfill material, creating a strong mechanical bond that significantly enhances the structural integrity of the semiconductor assembly.

In an embodiment method 600, step 610 comprises adding molding 118, an additional underfill layer 122, and other optional features. The molding 118 may comprise a thermosetting polymer, such as epoxy, which is applied using a transfer molding process. This involves placing the semiconductor assembly into a mold cavity and injecting the molding compound under high pressure. The compound flows around the active devices 104, 106 and the interconnect structure 102, filling any remaining voids and forming a protective encapsulation. Once the mold compound is in place, it may be cured through a controlled heating process, solidifying into a robust, protective layer that shields the components from environmental factors such as moisture, dust, and mechanical damage.

Other optional features that can be integrated include the incorporation of heat spreaders or thermal vias to further enhance thermal performance. These elements may be made from materials with high thermal conductivity, such as copper or aluminum, may be strategically placed to draw heat away from critical areas. Additionally, electromagnetic interference (EMI) shielding layers may be added to reduce the impact of external electromagnetic fields on the device's performance. These shielding layers may include conductive materials applied as a coating or embedded within the molding compound.

The various embodiments disclosed herein may provide various advantages and improvements. The dummy die 110 being attached with the adhesive layer 116 may enable chip-on-wafer silicon die stacking with flexible dummy die integration, reduce underfill bleeding width, and provide package edge/corner stress mitigation. The adhesive layer 116 may have a tunable thickness for adjusting to particular applications. During manufacturing, the adhesive layer 116 may enable controlled wafer warpage with silicon chip placement.

Embodiments of the present disclosure related to a semiconductor device 100 that includes a substrate 114, an interposer 120 over the substrate 114, an interconnect structure 102 over the interposer 120, and one or more active devices 104, 106 attached to the interconnect structure 102, the one or more active devices 104, 106 being electrically connected to the interconnect structure 102 through a plurality of conductive bumps 108. The semiconductor device 100 includes a dummy die 110 attached to the interconnect structure 102 by an adhesive layer 116, wherein the adhesive layer 116 comprises one of a die attach film (DAF) layer, a film over wire (FOW) layer, or a non-conductive film (NCF) layer. A bottom surface 110e of the dummy die 110 is distally spaced a greater distance from the substrate 114 than one or more bottom surface 104e of active device 104 and/or bottom surface 106e of the active device 106.

In one embodiment, wherein the adhesive layer 116 may have a height greater than or equal to 1 μm and less than or equal to 200 μm. In one embodiment, the adhesive layer 116 may have a width W1, the dummy die has a width W2, 0.5≤W1/W2≤1, and W1>10 μm. In one embodiment, the adhesive layer 116 may have a height H1, the dummy die 110 may have a height H2, and the ratio of H2:H1≥100:1 and ≤500:1. In one embodiment, the one or more active devices 104, 106 may include a High Bandwidth Memory (HBM) device attached to the interconnect structure 102 through the conductive bumps 108, and wherein the one or more active devices 104, 106 may include a System on Chip (SoC) device attached to the interconnect structure 102 through the conductive bumps 108, the SoC device being electrically connected to the High Bandwidth Memory (HBM) device via the interconnect structure 102. In one embodiment, the interconnect structure 102 may include a redistribution layer (RDL) formed on a substrate, the redistribution layer being configured for providing electrical connections between the one or more active devices and external circuitry. In one embodiment, the redistribution layer (RDL) comprises a plurality of metallization layers separated by one or more dielectric layers. In one embodiment, the dummy die 110 may be positioned adjacent to at least a first active device 104, 106 and on a corner edge of the semiconductor device 100. In one embodiment, the dummy die 110 may include a material selected to match the coefficient of thermal expansion (CTE) of the interconnect structure, thereby minimizing stress and potential damage during thermal cycling. In one embodiment, the semiconductor device 100 may further include an underfill layer 112 disposed between the one or more active devices 104, 106 and the interconnect structure 102 and bounded by the dummy die 110 and the adhesive layer 116.

Embodiments of the present disclosure relate to a method for fabricating a semiconductor device. The method includes attaching a dummy die 110 to an interconnect structure 102 using an adhesive layer 116. The method includes attaching one or more active devices 104, 106 to the interconnect structure 102, the one or more active devices 104, 106 being electrically connected to the interconnect structure 102 through conductive bumps 108. The method includes applying an underfill layer 112 between the one or more active devices 104, 106 and the interconnect structure 102 such that the dummy die 110 and the adhesive layer 116 spatially blocks a flow of the underfill layer 112.

In one embodiment, the method may further include forming a mold 108 surrounding the active devices 104, 106 and the dummy die 110 and applying an additional underfill layer 122 outside of the mold 118. In one embodiment, attaching the dummy die 110 may include positioning the dummy die 110 adjacent to at least a first active device 104, 106 and on a corner edge of the semiconductor device 100. In one embodiment, attaching the one or more active devices 104, 106 to the interconnect structure 102 comprises electrically connecting a System on Chip (SoC) device to a High Bandwidth Memory (HBM) device via the interconnect structure 102. In one embodiment, attaching the dummy die 110 to the interconnect structure 102 using the adhesive layer 116 includes: applying the adhesive layer 116 to the interconnect structure 102; positioning the dummy die 110 onto the adhesive layer 116; and applying pressure and heat to bond the dummy die 110 to the interconnect structure 102.

Embodiments of the present disclosure relate to a chip-on-wafer system comprising a substrate and an interconnect structure above the substrate. The chip-on-wafer system includes a system-on-chip (SoC) device and a number of active devices adjacent to the SoC device and attached to the interconnect structure. The chip-on-wafer system includes a number of dummy dies adjacent to the SoC device and attached to the interconnect structure, wherein each dummy die is attached to the interconnect structure by an adhesive layer comprising one of a die attach film (DAF) layer, a film over wire (FOW) layer, or a non-conductive film (NCF) layer.

In one embodiment, a first dummy die 110 may be positioned between a first active device 104, 106 at a first corner of the chip-on-wafer system and a second active device 104, 106 at a second corner of the chip-on-wafer system. In one embodiment, a second dummy die 110 may be positioned between a third active device at a third corner of the chip-on-wafer system and a fourth active device at a fourth corner of the chip-on-wafer system. In one embodiment, a first active device 104, 106 may be positioned between a first dummy die 110 at a first corner of the chip-on-wafer system and a second dummy die 110 at a second corner of the chip-on-wafer system. In one embodiment, a second active device 104, 106 may be positioned between a third dummy die at a third corner of the chip-on-wafer and a fourth dummy die at a fourth corner of the chip-on-wafer system.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
an interposer over the substrate;
an interconnect structure over the interposer;
one or more active devices attached to the interconnect structure, the one or more active devices being electrically connected to the interconnect structure through a plurality of conductive bumps; and
a dummy die attached to the interconnect structure by an adhesive layer, wherein a bottom surface of the dummy die is distally spaced further from the substrate than one or more bottom surfaces of the active devices.

2. The semiconductor device of claim 1, wherein the adhesive layer has a height greater than or equal to 1 μm and less than or equal to 200 μm.

3. The semiconductor device of claim 1, wherein the adhesive layer has a width W1, the dummy die has a width W2, 0.5≤W1/W2≤1, and W1>10 μm.

4. The semiconductor device of claim 1, wherein the adhesive layer has a height H1, the dummy die has a height H2, and a ratio of H2:H1≥100:1 and ≤500:1.

5. The semiconductor device of claim 1, wherein the one or more active devices include a High Bandwidth Memory (HBM) device attached to the interconnect structure through the conductive bumps, and wherein the one or more active devices include a System on Chip (SoC) device attached to the interconnect structure through the conductive bumps, the SoC device being electrically connected to the High Bandwidth Memory (HBM) device via the interconnect structure.

6. The semiconductor device of claim 1, wherein the interconnect structure comprises a redistribution layer (RDL) configured for providing electrical connections between the one or more active devices and external circuitry.

7. The semiconductor device of claim 6, wherein the redistribution layer (RDL) comprises a plurality of metallization layers separated by one or more dielectric layers.

8. The semiconductor device of claim 1, wherein the dummy die is positioned adjacent to at least a first active device and on a corner edge of the semiconductor device.

9. The semiconductor device of claim 1, wherein the dummy die comprises a material selected to match the coefficient of thermal expansion (CTE) of the interconnect structure, thereby minimizing stress and potential damage during thermal cycling.

10. The semiconductor device of claim 1, further comprising an underfill layer disposed between the one or more active devices and the interconnect structure and bounded by the dummy die and the adhesive layer.

11. A method of fabricating a semiconductor device, the method comprising:
attaching a dummy die to an interconnect structure using an adhesive layer;
attaching one or more active devices to the interconnect structure, the one or more active devices being electrically connected to the interconnect structure through conductive bumps; and
applying an underfill layer between the one or more active devices and the interconnect structure such that the dummy die and the adhesive layer spatially blocks a flow of the underfill layer.

12. The method of claim 11, comprising forming a mold surrounding the active devices and the dummy die and applying an additional underfill layer outside of the mold.

13. The method of claim 11, wherein attaching the dummy die comprises positioning the dummy die adjacent to at least a first active device and on a corner edge of the semiconductor device.

14. The method of claim 11, wherein the adhesive layer comprises one of a die attach film (DAF) layer, a film over wire (FOW) layer, or a non-conductive film (NCF) layer.

15. The method of claim 11, wherein attaching the dummy die to the interconnect structure using the adhesive layer comprises:
applying the adhesive layer to the interconnect structure;
positioning the dummy die onto the adhesive layer; and
applying pressure and heat to bond the dummy die to the interconnect structure.

16. A chip-on-wafer system comprising:
a substrate;
an interconnect structure above the substrate;
a system-on-chip (SoC) device;
a plurality of active devices adjacent to the SoC device and attached to the interconnect structure; and
a plurality of dummy dies adjacent to the SoC device and attached to the interconnect structure, wherein each dummy die is attached to the interconnect structure by an adhesive layer comprising one of a die attach film (DAF) layer, a film over wire (FOW) layer, or a non-conductive film (NCF) layer.

17. The chip-on-wafer system of claim 16, wherein a first dummy die is positioned between a first active device at a first corner of the chip-on-wafer system and a second active device at a second corner of the chip-on-wafer system.

18. The chip-on-wafer system of claim 17, wherein a second dummy die is positioned between a third active device at a third corner of the chip-on-wafer system and a fourth active device at a fourth corner of the chip-on-wafer system.

19. The chip-on-wafer system of claim 16, wherein a first active device is positioned between a first dummy die at a first corner of the chip-on-wafer system and a second dummy die at a second corner of the chip-on-wafer system.

20. The chip-on-wafer system of claim 19, wherein a second active device is positioned between a third dummy die at a third corner of the chip-on-wafer system and a fourth dummy die at a fourth corner of the chip-on-wafer system.
